(19) United States
(12) Patent Application Publication
(10) Pub. No.: US 2004/0152296 A1
(43) Pub. Date: Aug. 5, 2004

(54) Hexamethyldisilazane treatment of low-k dielectric films

(75) Inventors: Phillip D. Matz, McKinney, TX (US); Patricia B. Smith, Colleyville, TX (US); Heungsoo Park, McKinney, TX (US); Changming Jin, Plano, TX (US); Andrew J. McKerrow, Dallas, TX (US)

Correspondence Address: TEXAS INSTRUMENTS INCORPORATED, P O BOX 655474, M/S 3999, DALLAS, TX, 75265

(73) Assignee: Texas Instruments Incorporated, Dallas, TX (US)

(21) Appl. No.: 10/357,993

(22) Filed: Feb. 4, 2003

(51) Int. Cl. H01L 21/31; H01L 21/469; H01L 21/4763

(52) U.S. Cl. 438/623; 438/637; 438/640; 438/624

(57) ABSTRACT

A method of forming an organosilicate low dielectric constant insulating layer (40) in an integrated circuit, and an integrated circuit structure having such a low-k insulating layer (40), are disclosed. In the case where the low-k dielectric material of the insulating layer (40) comprises an organosilicate glass, subsequent plasma processing has been observed to break bonds between silicon and organic moieties, either by replacing an organic group with a hydroxyl group or with hydrogen, or by leaving a dangling bond. Eventually, the damaged insulating layer (40) includes silanol molecules, which results in a degraded film. The disclosed method exposes the damaged insulating layer (40) to a silylation agent such as hexamethyldisilazane, which reacts with the damaged molecules, and forms molecules that restore the properties of the film.

### CROSS-REFERENCE TO RELATED APPLICATIONS

This application is related to our copending application Ser. No. ______ filed ______, entitled “Chemical Treatment of Low-K Dielectric Films” (Attorney's Docket No. TI-33703).

### STATEMENT REGARDING FEDERALLY SPONSORED RESEARCH OR DEVELOPMENT

Not applicable.

### BACKGROUND OF THE INVENTION

This invention is in the field of semiconductor integrated circuit manufacturing, and is more specifically directed to the formation and processing of dielectric films in semiconductor integrated circuits.

It is a fundamental goal, in the field of integrated circuit manufacturing, to design and manufacture integrated circuits to be as small as possible. As is fundamental in this field, the manufacturing cost of an integrated circuit corresponds strongly to the wafer area occupied by each integrated circuit die, not only by increasing the number of possible integrated circuits per manufactured wafer, but also by generally providing an increased theoretical yield for a given manufacturing defect density. In addition, the smaller device feature sizes involved in decreasing chip area also provide improved performance, and increased functionality per unit area.

Recent advances in the area of integrated circuit metallization technology have been important in decreasing the necessary chip area for modern integrated circuits. One such advance is the increased number of metal levels that are manufacturable in a device, providing both dramatic reduction in necessary chip area and corresponding dramatic increases in device density. Recent technological advances have also provided significant reductions in the line pitch of conductors in these multiple metal levels, also greatly increasing the functional density of the chip. The advent of copper metallization has also been important in providing reliable small line width conductors in modern integrated circuits. An example of a conventional copper damascene process is described in U.S. Pat. No. 6,410,426, assigned to Texas Instruments Incorporated and incorporated herein by this reference.

It is of course important to ensure good electrical isolation between adjacent metal conductors. By way of definition, the insulating material between conductors in the same metallization level is commonly referred to as the intermetal dielectric, or IMD, and the insulating material between conductors in adjacent metallization levels is referred to as the interlayer dielectric, or ILD. For performance and cost reasons, it is desirable to have adjacent conductors as close as possible to one another. This has necessitated the use of so-called “low-k” dielectric material for the insulator layers between metal conductors. Low-k dielectric materials refer to those insulating materials that have a dielectric constant lower than that of silicon dioxide. Because the capacitance between adjacent conductors depends on the dielectric constant of the insulating material that separates the conductors, as well as the thickness of this insulating material, a low-k dielectric material can be thinner than a higher-k dielectric material, while providing the same or better electrical isolation. The use of low-k dielectric materials is especially important in modern high-frequency integrated circuits.

Examples of modern low-k dielectric materials include fluorine-doped silicon dioxide (also referred to as fluorinated silicate glass, or FSG), organosilicate glass (OSG), thermoplastic organic polymers, aerogel, xerogel, and other conventional low-k insulator materials. The organosilicate glasses have become an important class of low-k dielectric material. Examples of commercially available OSG dielectric materials include the CORAL family of low-k dielectrics available from Novellus Systems, Inc., and MSQ low-k dielectric material available from JSR Corporation, of which LKD-5109 is an example. These materials are typically deposited by plasma-enhanced chemical vapor deposition (PECVD). These materials can serve as either or both the ILD and ILM insulating layers.

It has been observed, according to this invention, that these low-k dielectric materials are susceptible to damage from plasma processes that are performed after their deposition. Plasma etching of the dielectric film itself, or of other features, can damage the surface of the remaining low-k dielectric film. Plasma ash processes for removing masking material such as photoresist that defines the trench and via locations, also damage the exposed surfaces of the low-k dielectric. Plasma-enhanced chemical vapor deposition (PECVD) processes, such as for depositing a dielectric capping layer over the low-k dielectric material after trench and via etch in copper damascene processes, can also damage the low-k dielectric material.

To the extent that plasma damage to low-k dielectric films has been observed in the art, thermal annealing has been a common conventional technique for reducing this damage after it has already occurred.

In the case of OSG low-k dielectric materials, it has been discovered, in connection with this invention, that the plasma damage is caused by a chemical reaction between constituents of the OSG material and the excited species in the plasma. Specifically, it is believed, in connection with this invention, that the OSG material is damaged by the conversion of silicon-hydrocarbon bonds in the material to silicon-hydroxide bonds when the material is exposed to oxidizing or reducing plasmas. Examples of these undesirable reactions will now be described in further detail relative to FIGS. 1a through 1d.

FIG. 1a illustrates, in cross-section, a portion of a partially formed integrated circuit. Underlying structure 3 refers, in a general sense, to underlying structures and layers over which a subsequent metal conductor will be formed. As such, underlying structure 3 may include the underlying semiconductor substrate and any epitaxial layers, wells, and doped regions formed at a surface of the substrate, overlying insulator layers, conductive levels including polysilicon or metal gate layers and levels, and previous metal conductor levels, including refractory metals and copper or aluminum metallization. Low-k dielectric film 2 has been deposited over underlying structure 3, and in this example is formed of an organosilicate glass. As such, in this example, silicon atoms are bound to three oxygen atoms and to one methyl group (CH₃), corresponding to the organic content present in organosilicate glasses. As evident from FIG. 1a, dielectric film 2 has been etched, with photoresist mask 4 present at locations defined by photolithographic patterning. At the exposed locations, dielectric film 2 is etched through to underlying structure 3; alternatively, for example in the formation of a conductor trench, dielectric film 2 may only be partially etched through at this location.

FIG. 1b illustrates the reaction of the OSG resulting from a subsequent oxidizing plasma, such as used to remove the remaining portions of photoresist 4 from the surface of dielectric film 2. The plasma illustrated in FIG. 1b is an oxygen plasma, as conventionally used in the art for photoresist removal. As evident from FIG. 1b, the methyl group in molecules at the exposed sidewalls of dielectric film 2 has been replaced by hydroxyl (OH) group, as a result of the oxidizing plasma exposure. In effect, the bonds between the silicon atoms and the methyl groups in these surface molecules are lost or broken, with the hydroxyl group replacing the lost methyl groups. The Si—OH substituted moieties are referred to as “silanol” moieties.

FIG. 1c illustrates the undesired reaction of surface molecules in OSG dielectric film 2 in the presence of a reducing plasma, such as a hydrogen plasma. In this instance, the excited neutral and/or ionic hydrogen species also react with and displace the methyl group in OSG materials near the exposed surfaces of dielectric film 2, for example along the sidewalls of the etched trench or via as shown. The bonds are either left dangling (i.e., associated with an unpaired electron spatially localized at the site of the removed methyl group) in this instance, or a hydrogen atom attaches to the silicon atom in the place of the removed methyl group. After exposure to the reducing plasma, dielectric film 2 becomes vulnerable to additional reaction with moisture, as evident from FIG. 1d. Water molecules react with the modified dielectric moieties, attaching hydroxyl groups either to the dangling bonds at the surface of dielectric film 2, or replacing the hydrogen molecules that bonded to the silicon atom after the hydrogen plasma exposure, in either case forming silanol molecules. The overall reaction in this situation follows:

$$Si - {CH}_{3} + {H}_{2} + HOH {\to }^{plasma} Si - OH + {CH}_{4}$$

In the case of exposure to either hydrogen-containing or oxygen-containing plasmas, the Si—OH bonds at the surface of the OSG material have been observed, in connection with this invention, to degrade the integrity of low-k dielectric film 2. One form of degradation is the increase in the dielectric constant of the low-k dielectric material due to the presence of the silanol. In addition, the damaged OSG material has been observed to adsorb moisture. It has also been observed, in connection with the invention, that this degraded low-k dielectric material is vulnerable to chemical attack during exposure to wet chemical cleanups, which results in significant critical dimension (CD) loss of low-k dielectric film insulating structures.

As mentioned above, thermal annealing of the low-k dielectric film to negate already-occurred damage from plasma processing is known in the art. In connection with this invention, it is known that such thermal annealing removes physically adsorbed, but unreacted, moisture present at the surface of the low-k dielectric film. However, it has also been discovered, in connection with this invention, that the thermal activation of these silanol condensation reactions necessitates annealing temperatures in excess of 250° C. for prolonged periods of time such as on the order of 10³ to 10⁴ seconds, or annealing temperatures in excess of 400° C. for brief durations such as on the order of 10² to 10³ seconds. These temperatures and processing times are both technically and economically unfavorable, due to concerns of activating other thermal processes such as copper stress migration. Significant equipment costs and increases in manufacturing times are also involved in such annealing. In addition, plasma-damaged low-k dielectric films that are annealed according to conventional processes, while removing the physically adsorbed moisture, are vulnerable to the re-adsorption of moisture and subsequent reaction which result in the formation of silanol molecules in the low-k dielectrics and the corresponding degradation of these films.

Similar effects are believed to occur in other low-k dielectric materials with silicon-hydrocarbon bonds that are converted to silanol when exposed to oxidizing or reducing plasmas.

### BRIEF SUMMARY OF THE INVENTION

It is therefore an object of this invention to provide a method of treating low-k dielectric films, and a resulting structure from such a method, in which plasma damage of the dielectric films is negated.

It is a further object of this invention to provide such a method and structure that retains the overall profile of the low-k dielectric film structures.

It is a further object of this invention to provide such a method and structure that yields acceptable integration results with plasma processing following the formation of low-k dielectric films.

Other objects and advantages of this invention will be apparent to those of ordinary skill in the art having reference to the following specification together with its drawings.

The present invention may be implemented in a method of fabricating an integrated circuit, and a structure formed by such a method, in which a low dielectric constant (“low-k”) film is formed, and locations of the film etched to receive conductive plugs or metal conductors. Following subsequent plasma processes, such as plasma etch of the film or of overlying conductors, or plasma removal of overlying photoresist, the low-k dielectric film is exposed to a silylation agent, preferably hexamethyldisilazane (HMDS). The HMDS may be in liquid or vapor form, in a plasma or a non-excited state. The HMDS reacts with Si—OH bonds formed in the dielectric films as a result of the plasma exposure, converting those species to the silicon-hydrocarbon species similar to those initially present in the low-k OSG dielectric material prior to the plasma exposure.

### BRIEF DESCRIPTION OF THE SEVERAL VIEWS OF THE DRAWING

FIGS. 1a through 1d are cross-sectional views of a portion of an integrated circuit structure, formed according to conventional methods, illustrating the reactions due to exposure of low-k dielectric films to plasma.

FIGS. 2a through 2d are cross-sectional views of a portion of an integrated circuit structure, illustrating its manufacture according to a first preferred embodiment of the invention.

FIG. 3 is a cross-sectional view of a portion of the integrated circuit of FIGS. 2a through 2d, illustrating the reactions for repair of plasma damage according to the preferred embodiment of the invention.

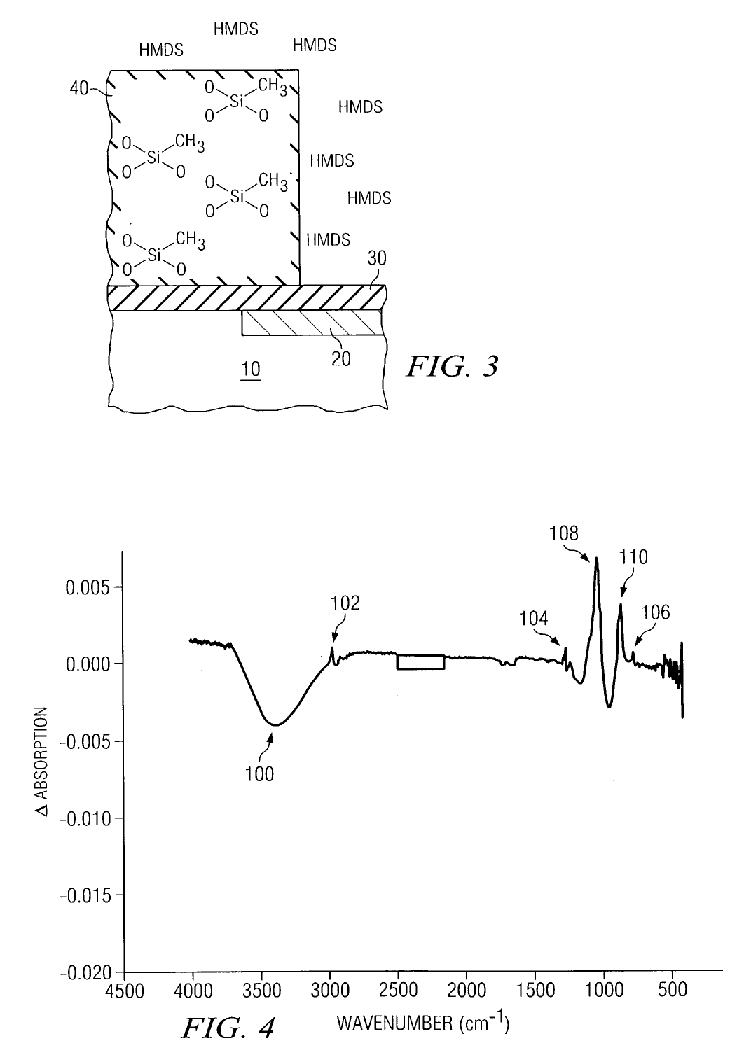

FIG. 4 is an absorption spectrum difference plot illustrating differences in the composition of low-k dielectric film following the plasma repair process according to the preferred embodiments of the invention.

FIGS. 5a through 5g are cross-sectional views of a portion of an integrated circuit structure, illustrating its manufacture according to a second preferred embodiment of the invention.

### DETAILED DESCRIPTION OF THE INVENTION

The present invention will be described in connection with the formation of multiple level metal conductors in an integrated circuit, and specifically in connection with the copper metallization formed by way of a damascene process. It is believed that this invention is especially beneficial when used in that process. However, it is also contemplated that this invention will provide benefits in many other applications using low dielectric constant insulating films, and at other stages of the manufacturing process. It is therefore to be understood that this description is provided by way of example only, and is not intended to hinit the scope of the invention as claimed.

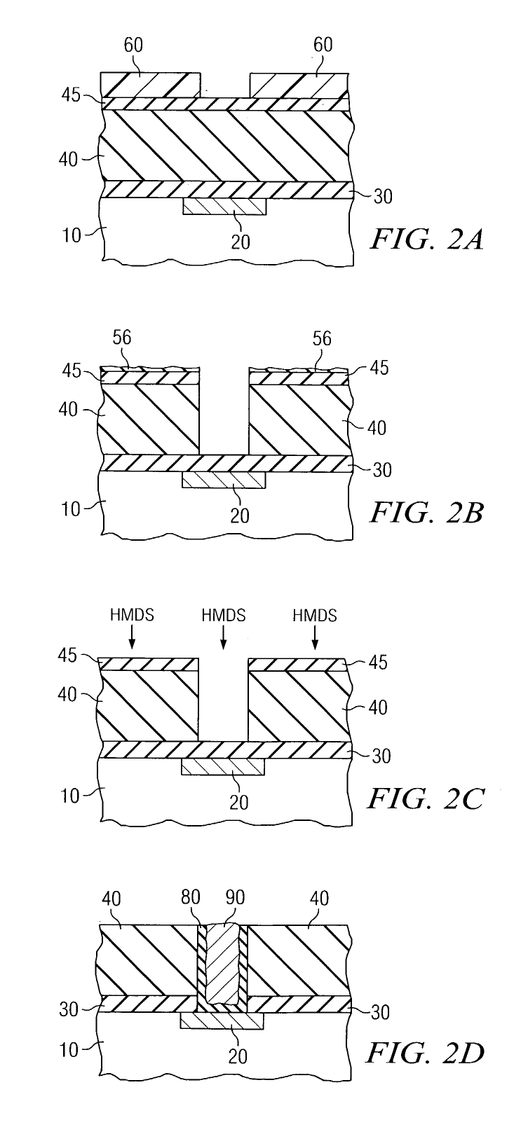

Referring now to FIGS. 2a through 2d, the construction of an integrated circuit according to a first preferred embodiment of the invention will now be described. This example refers to a single damascene copper metallization process, although of course the invention may be used in connection with other processes and process flows. FIG. 2a illustrates, in cross-section, a portion of a partially fabricated integrated circuit, having metal conductor 20 disposed in a trench, and isolated from other trench conductors and active structures by insulator layer 10. Insulator layer 10 overlies a semiconducting surface of a substrate (not shown), and as such active devices such as transistors, resistors, diodes and the like are disposed beneath insulator layer 10. Insulator layer 10 is preferably formed of a low dielectric constant material, such as an organosilicate glass (OSG). In this regard, insulator layer 10 is also preferably formed according to the method of this first preferred embodiment of the invention. For purposes of this description, however, this method will be described in connection with the formation of overlying insulator layer 40.

Etch stop layer 30 is disposed over insulator layer 10 and metal conductor 20, in this embodiment of the invention. Low dielectric constant (“low-k”) insulator layer 40 is disposed over etch stop layer 30. In this embodiment of the invention, low-k insulator layer 40 is preferably an organosilicate glass, preferably an OSG. Examples of OSG materials include the CORAL family of low-k dielectrics available from Novellus Systems, Inc., and the LKD series of dielectric materials available from JSR Corporation, of which LKD-5109 is an example. Low-k insulator layer 40 is deposited in the conventional manner for such material, for example by plasma-enhanced chemical vapor deposition (PECVD). Etch stop layer 30 is preferably formed of a material that is resistant to etchants for etching low-k insulator layer 40, as used to form a via to metal conductor 20, for example. Materials useful for etch stop layer 30 include silicon nitride, silicon carbide, and other etch-resistant materials, preferably having relatively low dielectric constants.

Hardmask layer 45 is formed over the surface of low-k insulator layer 40. Hardmask layer 45 is preferably of a material that is resistant to etchants used to etch vias through low-k insulator layer 40, and may be formed of either a conductive or insulating material. Examples of materials for hardmask layer 45 include silicon nitride, silicon carbide, tantalum nitride, and titanium nitride.

As shown in FIG. 2a, photoresist 60 has been deposited over the surface of hardmask layer 45, and photolithographically exposed and developed to define the location at which a via is to be formed through insulator layer 40, extending to lower level metal conductor 20. The particular material for photoresist 60 will depend upon the photolithography wavelength and process to be used, as well as upon the dimensions of the eventual via. A bottom anti-reflective coating, or BARC, (not shown) may optionally be dispensed prior to photoresist 60, to underlie photoresist 60.

After the patterning of photoresist 60, hardmask layer 45 is first etched where not protected by photoresist 60, and then low-k insulator layer 40 is etched at those locations. These etches are preferably plasma etches, of sufficient energy, duration, and plasma conditions to first remove hardmask layer 45 and then to anisotropically etch low-k insulator layer 40 through to etch stop layer 30, resulting in the structure illustrated in FIG. 2b. The etchant used to remove hardmask layer 45 will of course depend on the composition of that layer. An example of a suitable etch for low-k insulator layer 40 formed of an OSG is a plasma etch with fluorocarbons as the activated species. The masking portions of photoresist 60 are reduced by the etch, leaving photoresist residue 56 at the protected locations of hardmask layer 45 and low-k insulator layer 40, as shown in FIG. 2b. Residue 56 is then removed from the surface of hardmask layer 45, preferably by way of exposure to a plasma, as conventional in the art.

The plasma process used to remove photoresist residue 56 and other polymeric residues causes damage to the exposed portions of low-k insulator layer 40 after this via etch. As described above, the plasma process used to remove the photoresist and other polymeric residues causes undesirable reactions in OSG at the exposed sidewalls of low-k insulator layer 40, so that the methyl groups bonded to the silicon atoms in OSG are removed. Silanol functionality, or Si—OH groups, may be formed at the sidewall surfaces by an oxidizing or reducing plasma. These silanol bonds directly increase the dielectric constant of insulator layer 40 at its surface locations, and thus degrade the electrical isolation provided by insulator layer 40 between adjacent conductors. The silanol also tends to adsorb moisture during subsequent processes, which will further degrade the properties of insulating layer 40. In addition, it has been observed that the presence of the silanol species at the surface of the sidewalls of the etched via renders these portions of insulator layer 40 vulnerable to etching during subsequent wet cleanups, such as occurs typically following the plasma cleaning processes.

If a hydrogen or other reducing plasma ash is used to remove residue 56, dangling bonds or Si—H bonds form in the surface molecules of OSG insulator layer 40, along the exposed sidewalls of the via. These bonds then react with moisture in the ambient, or introduced in later wet processes, to form silanol molecules in insulator layer 40.

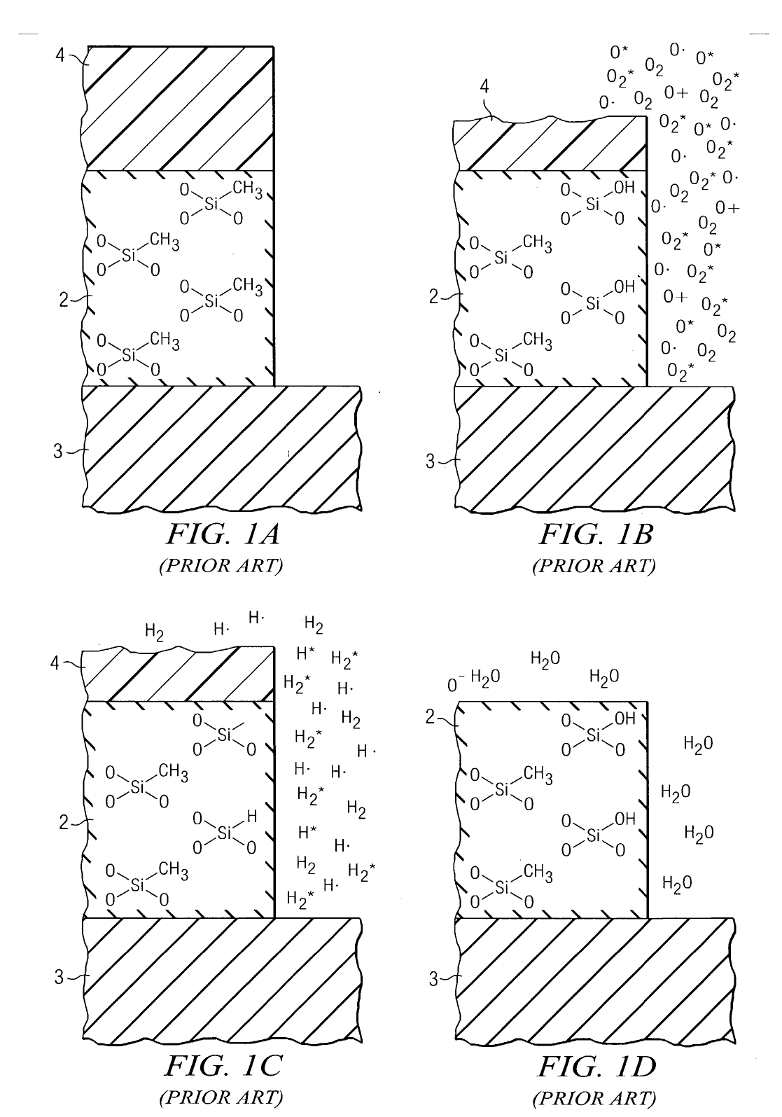

In either case, the sidewalls of insulator layer 40 have molecules at the surface that have silanol bonds, consisting of hydroxyl groups bonded to silicon atoms in place of the original organic groups, in the manner illustrated in FIGS. 1a and 1d described above relative to the Background of the Invention.

According to the preferred embodiment of the invention, after the removal of photoresist residue 56, the structure is exposed to a silylation agent, a preferred agent being hexamethyldisilazane (HMDS), as illustrated in FIG. 2c. HMDS is the preferred silylation agent for several reasons, including its availability in semiconductor grade, and because HMDS is a liquid at room temperature. In addition, as will be described below, the use of HMDS according to the preferred embodiments of the invention result in reaction by-products that are conveniently volatile. According to the preferred embodiments of the invention, the HMDS exposure can be carried out in several ways. Most simply, the HMDS may be in a neat liquid phase, into which the partially manufactured integrated circuit wafers may be immersed, or which may be sprayed or dispensed over the integrated circuit wafers. Alternatively, the HMDS may be in a vapor phase, introduced in situ in the same chamber in which the plasma ash was carried out, or alternatively ex situ in a separate chamber or process tool into which the integrated circuit wafer or wafers are placed.

The reaction of the HMDS with the silanol bonds in insulator 40 is:

HMDS+≡Si—OH→Si—O—Si—(CH₃)₃+[rxn-byproduct]

or, in terms of the chemical compounds:

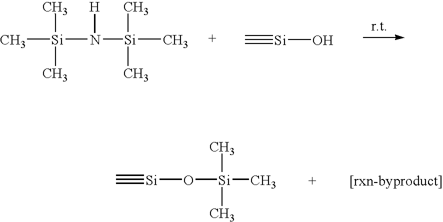

This reaction thus reduces the damage to OSG insulator layer 40, by reacting HMDS with the hydroxyl groups that are bonded to the silicon atoms in the film and forming oxygen-bridged silicon trimethyl, which is bound to the silicon previously present in the OSG itself. The rxn byproduct (e.g., NH₃) of this room temperature reaction is volatile, and is readily exhausted from the chamber, tool, or hood in which the HMDS reaction is being performed. This byproduct also does not react with the OSG insulator layer 40, or other layers of OSG in the structure. In addition, both the HMDS and the NH₃ byproduct are believed to not poison any photoresist that may be present at the time of the reaction. As such, the HMDS process illustrated in FIG. 2c may alternatively be performed after the deposition and patterning of the next layer of photoresist, if more efficient for the overall process.

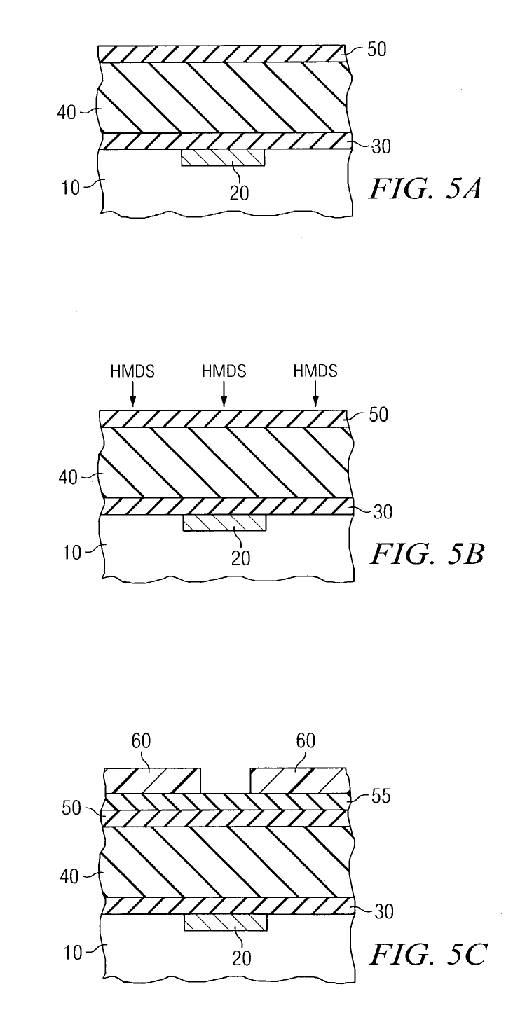

The reduction in the number of silanol species, and the corresponding increase in silicon methyl groups, resulting from this embodiment of the invention have been verified by experiment. FIG. 4 is an absorption spectrum difference plot generated by Fourier Transform Infrared Spectroscopy (FTIR), taken of a portion of OSG insulator material, after processing with HMDS according to this embodiment of the invention. As known in the art, FTIR is a technique by way of which energy of varying wavelength in the infrared band is generated and irradiates the sample under analysis. The frequencies at which this energy is absorbed by the material corresponds to quantum transition energies of the material. Specifically, if the material has a transition that is related by Planck's constant to the frequency of the incident radiation, the radiation is absorbed by the material. Conversely, if the incident radiation frequency does not satisfy the Planck expression, then the radiation will be transmitted. A plot of the frequency of the incident radiation against a measure of the percent of the radiation that is absorbed by the sample is the absorption spectrum of the material.

FIG. 4 is a difference plot, corresponding to the difference in absorbance between OSG material before and after treatment with HMDS according to the preferred embodiment of the invention. In this experiment, the OSG material was soaked in water prior to the first FTIR measurement before HMDS treatment. Those frequencies (wavenumbers) for which no difference is seen appear flat at about the 0.000 level. As evident from FIG. 4, lower frequency negative absorption difference 100 at a wavenumber of about 3500 indicates a significant loss of silanol (Si—OH). Positive absorption differences are evident at several wavenumbers (frequencies). Increases 102, 104, 106 at wavenumbers of about 3000, 1400, and 800, respectively, indicate increases in Si—CH₃ groups, while strong positive peaks 108, 110 at wavenumbers about 1000±100 indicate increases in Si—O—Si bonds. This experimental result is believed to confirm that the HMDS reacts with silanol bonds in the manner described in connection with this preferred embodiment of the invention.

In addition, FIG. 4 illustrates that insulator film 40 is structurally different from conventional OSG insulator films, in that a significant decrease in the number of silanol molecules, and an increase in Si—CH₃ and Si—O—Si bonds, can be detected by modern measurement techniques, such as the FTIR technique.

Following the HMDS treatment of FIG. 2c, etch stop layer 30 is then removed from the bottom of the via through insulator layer 40. This etch may be a brief plasma etch, or a brief wet etch, and may remove remaining portions of hardmask layer 45. If a plasma etch is used to clear etch stop layer 30 from the bottom of the via, it may be beneficial to perform the HMDS treatment after the etch of etch stop layer 30, rather than before etch stop layer 30 is removed as shown in FIG. 2c. Indeed, the HMDS treatment according to this embodiment of the invention may be performed at any stage in the process after plasma exposure of insulator layer 40 and prior to the deposition of metal conductors into the etched vias or openings.

The metallization process then continues, once etch stop layer 30 is removed from the bottom of the via. In this exemplary implementation of this first preferred embodiment of the invention, liner layer 80 is formed of the desired material overall. Examples of suitable materials for use as liner layer 80 include titanium nitride, tantalum nitride, tungsten nitride, and the like. After deposition, liner layer 80 will extend not only into the via to lower level conductor 20, but also over the surface of insulating layer 40. Metal 90, preferably copper, is then deposited (or, in the case of copper, electroplated over a PVD copper seed layer) overall, into the via through insulator layer 40 and also on the surface of insulator layer 40 and liner layer 80. Chemical mechanical polishing (CMP) is then performed to remove metal 90 and liner layer 80, and perhaps also hardmask layer 45 (especially if layer 45 is conductive), from the surface of insulator layer 40, leaving a conductive plug within the via through insulator layer 40, flush with the surface of insulator layer 40. The remainder of the interconnect processing then continues in the same, cyclical, manner, to form additional metal conductor levels.

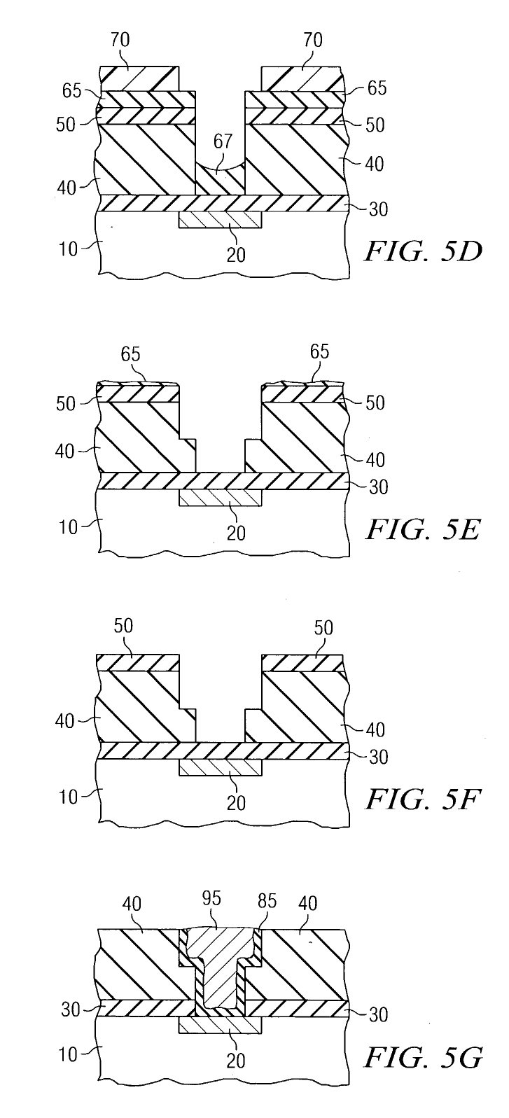

Referring now to FIGS. 5a through 5g, the fabrication of an integrated circuit according to a second preferred embodiment of the invention will now be described. The same elements in this embodiment of the invention that are also present in the first embodiment of the invention described in this specification will be referred to by the same reference numerals.

FIG. 5a illustrates lower level conductor 20 disposed within a trench formed in low-k insulator layer 10, over which etch stop layer 30 is disposed, as before. Low-k insulator layer 40, preferably formed of OSG as before, is then formed to overlie etch stop layer 30, as shown in FIG. 5a. According to this second preferred embodiment of the invention, cap dielectric layer 50 is then formed to overlie low-k insulator layer 40, as shown in FIG. 5a. The purpose of cap dielectric layer 50 is to help protect the remaining thickness of low-k insulator layer 40 from the etches used to form vias and trenches therethrough, and from CMP after metal deposition. In this example, cap dielectric layer 50 is preferably formed of silicon carbide or silicon carbonitride; other suitable materials include titanium aluminum nitride, titanium nitride, aluminum nitride, tantalum aluminide, tantalum aluminum nitride, and similar materials.

However, cap dielectric layer 50 is generally formed by a plasma-based process, such as plasma enhanced chemical vapor deposition (PECVD). Because this deposition involves a plasma, the exposed top surface of low-k insulating layer 40 is exposed to the plasma, and the MSQ species at that top surface are damaged. This plasma damage is the same as that described above, in that Si—CH₃ bonds are broken, in favor of silanol (Si—OH), silicon-hydrogen (Si—H) bonds, or dangling bond formation. As before, the silicon-hydrogen and dangling bonds are converted to silanol bonds upon subsequent exposure to moisture.

According to this embodiment of the invention, an HMDS treatment is carried out after the plasma-enhanced deposition of cap layer 50, as shown in FIG. 5b. The HMDS reagent may be in either the liquid or vapor phase, and the exposure of the structure to HMDS may be carried out in situ in the same process chamber as the cap layer 50 deposition, or alternatively may be performed in a separate process chamber, process tool, or hood. According to this embodiment of the invention, however, the HMDS exposure is not performed in a plasma, but rather the HMDS molecules and constituents remain in a non-excited state. Because no plasma is involved, the HMDS molecules are able to penetrate cap dielectric layer 50 and reach the damaged surface of low-k insulator layer 40. It is believed that the exposure of HMDS under plasma conditions would limit the depth to which the HMDS species can penetrate, and as such the non-plasma HMDS treatment is preferred in this embodiment of the invention.

This HMDS treatment repairs the plasma damage to low-k insulator layer 40 that occurred during cap deposition, as described above. In summary, the hydroxyl groups bonded to silicon atoms in the film react with the HMDS molecules, producing oxygen-bridged silicon trimethyl bound to silicon previously present in insulator layer 40. Degradation of the dielectric constant of insulator layer 40, and the vulnerability of the damaged film to moisture and subsequent etching reactions, are thus avoided.

Referring to FIG. 5c, the fabrication of the integrated circuit structure continues, with the deposition and application of BARC layer 55 and photoresist 60. Photoresist 60 is then photolithographically exposed and developed to define the locations of vias to be etched through low-k insulator layer 40. Following the patterning of photoresist 60 as shown in FIG. 5c, BARC layer 55 and underlying low-k insulator layer 40 are etched by a conventional plasma etch, for example involving activated fluorocarbon species, to form the vias therethrough. The resulting structure substantially corresponds to that illustrated in FIG. 2b described above, with residue 56 possibly also including some of BARC layer 55.

Following the trench etch, another HMDS treatment may be performed, if desired. However, according to this embodiment of the invention, trenches are also to be etched partially into insulator layer 40, including at the location of the now etched via, after which an HMDS treatment will be performed as described below. As such, an HMDS treatment at this point is optional.

As shown in FIG. 5d, the photolithographic patterning of trenches to be formed into low-k dielectric layer 40 is performed next. BARC layer 65 is formed over the surface of cap dielectric 50, and photoresist layer 70 is dispensed over BARC layer 65. After photolithographic exposure and development, the remaining portions of photoresist layer 70 as shown in FIG. 5d define the locations at which trenches are to be etched into insulating layer 40. As evident from FIG. 5d, the trench is somewhat wider than the previously etched via, and as such the masking portions of photoresist layer 70 are pulled back from the edges of the via. To the extent that BARC layer 65 falls within the previously etched via, filaments 67 are formed at the via bottoms as shown in FIG. 5d.

As is well known in the dual damascene process, trenches are formed both at via locations, as shown in FIG. 5d, and also elsewhere at the surface of cap dielectric layer 50 and low-k insulating layer 40 at which copper conductors are to run along the surface of integrated circuit, between or away from via locations. These locations are not shown in FIG. 5d, but those skilled in the art having reference to this specification will readily understand the formation of such trenches in the dual damascene context.

Plasma etch of cap dielectric layer 50 and low-k insulating layer 40 is then carried out. Because of the dissimilarities in materials between cap dielectric layer 50 and insulating layer 40, it is preferred that a two step etch be performed, with the first etch selectively etching cap dielectric layer 50 relative to low-k insulating layer 40, to provide process margin. The second etch step, which forms the trenches into insulating layer 40, is preferably a timed plasma etch, to form the wider trenches into insulating layer 40 to a desired trench depth, as shown in FIG. 5e. Photoresist layer 70 and BARC layer 65 are removed by these etches, leaving masking residue 65 at the surface of cap dielectric layer 50, as shown in FIG. 5e.

The plasma trench etch of cap dielectric layer 50 and low-k insulating layer 40 again causes plasma damage to the surfaces of the sidewalls of insulating layer 40 within the trenches and vias. According to this embodiment of the invention, the structure is now exposed to HMDS, to repair this plasma damage, as shown in FIG. 5f. As in the first embodiment of the invention, the HMDS may be in liquid or vapor phase, and applied to the integrated circuit wafer in situ with the plasma etch, or ex situ in a separate process chamber, tool, or hood. Because the top surface of insulating layer under cap dielectric layer 50 has already been treated, the HMDS exposure at this stage of the process may be plasma-assisted, although it is contemplated that a non-plasma exposure will be adequate.

Alternatively, the HMDS treatment of the top surface of insulator layer 40 for plasma damage from the plasma deposition of cap dielectric layer 50 may be omitted, in favor of the post-etch HMDS treatment. In this alternative approach, however, the post-etch HMDS treatment must be performed without plasma assistance, to permit the HMDS to both treat the exposed sidewalls of insulator layer 40 and also the top surface of insulator layer 40 underlying cap dielectric 50.

As described above, the HMDS treatment of low-k insulator layer 40 repairs the plasma damage by releasing the hydroxyl groups from the molecules, reacting these hydroxyl groups with the HMDS molecules to negate the plasma damage. Degradation in the dielectric constant is avoided, as is the vulnerability of the film to subsequent reaction with moisture exposure and with wet chemical cleanups and thus the potential for critical dimension loss due to this vulnerability.

Following the HMDS treatment, fabrication of the conductor is then carried out. According to this embodiment of the invention, liner layer 85 is deposited into the vias and trenches, and over the top surface of cap dielectric. As before, liner layer 85 typically consists of a refractory metal, refractory metal nitride, or both. Metal 95 is then deposited overall, both into the vias and trenches and also over the surface of cap dielectric layer 50. Preferably, metal 95 is copper, in which case the deposition is carried out by electroplating over a copper seed layer deposited by PVD. CMP then planarizes the structure, rendering metal 95 and liner layer 85 flush with the surface of insulator layer 40. Cap dielectric layer 50 may no longer be necessary, depending on the composition of insulator layer 40. If not necessary, cap dielectric layer 50 may be removed in the CMP planarization, as shown in FIG. 5g. The remainder of the back-end processing, including the repeated forming of low-k insulator layers, via and trench etch, and metal deposition for additional metal levels, may then be carried out.

According to each of the embodiments of the invention described above, conventional test and packaging operations are carried out after completion of the fabrication of the semiconductor wafer containing the fabricated integrated circuits. These operations include electrical testing of the integrated circuits in wafer form, dicing and packaging of individual integrated circuits, and final manufacturing testing and burn-in of the packaged integrated circuits. It is contemplated that these conventional processes do not materially change or alter the composition of the integrated circuits made according to the methods of this invention.

Various alternatives to these exemplary implementations of the preferred embodiments of the invention will be apparent to those skilled in the art, having reference to this specification. For example, the trench locations may be kept away from all vias, particularly when the vias are to be filled with conductive plugs of a material other than that of the metal levels. It is contemplated that other process alternatives will be apparent to those skilled in the art having reference to this specification.

It is also contemplated that silylation agents other than HMDS may be used to repair plasma damage to low-k dielectric films in a similar manner as the HMDS treatments described above. Examples of such alternative silylation agents include N,O-bis(trimethylsilyl)acetamide (BSA); N,O-Bis(trimethylsilyl)trifluoroacetamide (BSTFA); ethyldimethylsilyl chloride; isopropyldimethylsilyl chloride; N,O-(bis)silylacetamide; N-Trimethylsilyl-N-methyltrifluoroacetamide (MSTFA); N-Tertiarybutylsilyl-N-methyltrifluoracetamide (MTBSTFA); tertiarybutyldimethylchlorosilane (TBDMCS); tertiarybutyldimethylsilyl chloride (TBDMSCl); N-Tertiarybutyldimethylsilylimidazole; (TBDMSIM); trimethylbromosilane (TMBS); trimethylchlorosilane (TMCS); N-Trimethylsilyldiethylamine (TMSDEA); trimethylsilylimidazole (TMSIM).

In each case, this invention provides important advantages in modern integrated circuit fabrication. This invention enhances the low dielectric constant properties of modern dielectric materials, such as OSG, by repairing damage to the chemical structure of the films caused by plasma processes. In addition, the resulting low-k dielectric structures have improved structural and chemical stability as a result of this invention, allowing the reliable fabrication of insulating structures of ever-shrinking dimensions. These and other advantages are provided by this invention.

While this invention has been described according to its preferred embodiments, it is of course contemplated that still other modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

What is claimed is:

1. A method of fabricating an integrated circuit at a surface of a substrate, comprising the steps of:
forming active devices at the surface;
depositing an organic low dielectric constant insulating layer over the active devices;
subjecting the insulating layer to a plasma;
after the subjecting step, exposing the insulating layer to a silylation agent; and
after the exposing step, forming a metal conductor near the insulating layer.

2. The method of claim 1, wherein the silylation agent is hexamethyldisilazane.

3. The method of claim 1, wherein the insulating layer comprises an organosilicate glass.

4. The method of claim 1, further comprising:
patterning a masking layer at the surface of the insulating layer, to define locations at which openings are to be etched into the insulating layer; and
etching the insulating layer, using the patterned masking layer as a mask;
wherein the step of subjecting the insulating layer to a plasma comprises:
after the etching step, removing remaining portions of the patterned masking layer using a plasma process.

5. The method of claim 4, wherein the etching step comprises plasma etching the insulating layer.

6. The method of claim 4, wherein the removing step is performed in a plasma chamber;
and wherein the exposing step is performed in the plasma chamber.

7. The method of claim 6, wherein the exposing step is performed in a plasma.

8. The method of claim 4, wherein the removing step is performed in a plasma chamber;
and further comprising:
removing the substrate from the plasma chamber prior to the exposing step.

9. The method of claim 1, wherein the step of subjecting the insulating layer to a plasma comprises:
depositing a cap dielectric layer over the insulating layer.

10. The method of claim 9, further comprising:
after the depositing step, patterning a masking layer at the surface of the insulating layer, to define locations at which openings are to be etched into the insulating layer; and
etching the cap dielectric layer and the insulating layer, using the patterned masking layer as a mask.

11. The method of claim 10, wherein the exposing step is performed prior to the patterning step.

12. The method of claim 11, wherein the step of subjecting the insulating layer to a plasma further comprises:
after the etching step, removing remaining portions of the patterned masking layer using a plasma process;
and further comprising:
after the removing step, again exposing the insulating layer to hexamethyldisilazane.

13. The method of claim 9, further comprising:
after the depositing step, patterning a masking layer at the surface of the insulating layer, to define locations at which openings are to be etched into the insulating layer; and
etching the cap dielectric layer and the insulating layer, using the patterned masking layer as a mask.
wherein the step of subjecting the insulating layer to a plasma further comprises:
after the etching step, removing remaining portions of the patterned masking layer using a plasma process;
and wherein the exposing step is performed after the removing step.

14. The method of claim 2, wherein the exposing step exposes the insulating layer to hexamethyldisilazane in the liquid phase.

15. The method of claim 2, wherein the exposing step exposes the insulating layer to hexamethyldisilazane in the vapor phase.

16. The method of claim 1, further comprising:
patterning a masking layer at the surface of the insulating layer, to define locations at which openings are to be etched into the insulating layer; and
etching the insulating layer, using the patterned masking layer as a mask;
wherein the step of subjecting the insulating layer to a plasma comprises:
after the etching step, removing remaining portions of the patterned masking layer using a plasma process;
and wherein the step of forming a metal conductor comprises depositing a metal into the openings formed in the etching step.

17. The method of claim 16, wherein the metal comprises copper.

18. An integrated circuit, comprising:
active devices disposed near a surface of a substrate;
a first organic low dielectric constant insulating layer disposed over the active devices, and formed according to a process comprising the steps of:
depositing the first insulating layer near the surface;
subjecting the first insulating layer to a plasma; and
after the subjecting step, exposing the first insulating layer to a silylation agent; and
a first metal conductor, disposed near the first insulating layer.

19. The integrated circuit of claim 18, wherein the silylation agent is hexamethyldisilazane.

20. The integrated circuit of claim 18, further comprising:
a second organic low dielectric constant insulating layer disposed over the active devices, over the first insulating layer, and over the first metal conductor, and formed according to a process comprising the steps of:
depositing the second insulating layer;
subjecting the second insulating layer to a plasma; and
after the subjecting step, exposing the second insulating layer to a silylation agent; and
a second metal conductor, disposed near the second insulating layer.

21. The integrated circuit of claim 18, wherein the first insulating layer comprises an organosilicate glass.

22. The integrated circuit of claim 18, wherein the process of forming the first insulating layer further comprises:
patterning a masking layer at the surface of the first insulating layer, to define locations at which openings are to be etched into the first insulating layer; and
etching the first insulating layer, using the patterned masking layer as a mask;
and wherein the step of subjecting the first insulating layer to a plasma comprises:
after the etching step, removing remaining portions of the patterned masking layer using a plasma process.

23. The integrated circuit of claim 18, wherein the step of subjecting the insulating layer to a plasma comprises:
depositing a cap dielectric layer over the first insulating layer.
wherein the etching step also etches the cap dielectric layer;
and wherein the exposing step is performed prior to the patterning step.

24. The integrated circuit of claim 23, wherein the process further comprises:
after the etching step, removing remaining portions of the patterned masking layer using a plasma process; and
after the removing step, again exposing the insulating layer to a silylation agent.

25. A method of fabricating an integrated circuit at a surface of a substrate, comprising the steps of:
forming active devices at the surface;
depositing an organic low dielectric constant insulating layer over the active devices, the insulating layer comprising a material having molecules with silicon-hydrocarbon bonds;
subjecting the insulating layer to a plasma, in which at least some of the silicon-hydrocarbon bonds are broken;
after the subjecting step, exposing the insulating layer to a substance that reacts with molecules in the insulating layer in which the silicon-hydrocarbon bonds were broken in the subjecting step, to form molecules having silicon-hydrocarbon bonds; and
after the exposing step, forming a metal conductor near the insulating layer.

26. The method of claim 25, wherein the insulating layer comprises an organosilicate glass.

27. The method of claim 25, wherein the substance comprises a silylation agent.

28. The method of claim 25, wherein the substance comprises hexamethyldisilazane.
